(19) United States
(12) Patent Application Publication
(10) Pub. No.: US 2026/0282276 A1
(43) Pub. Date: Sep. 17, 2026

(54) COMPUTER SYSTEM HAVING A PIVOTING VERTICAL PANEL

(71) Applicant: QARNOT COMPUTING, Montrouge (FR)

(72) Inventors: Louis MIKOLAJCZAK, Clamart (FR); Paul BENOIT, Paris (FR); Clément PELLEGRINI, Montrouge (FR)

(21) Appl. No.: 18/872,703

(22) PCT Filed: May 23, 2023
(86) PCT No.: PCT/EP2023/063811

§ 371 Date: Dec. 6, 2024

(30) Foreign Application Priority Data
Jun. 28, 2022 (FR) FR2206467

(51) Int. Cl. H05K 7/20

(52) U.S. Cl. CPC H05K 7/20272; H05K 7/20772

(57) ABSTRACT

A computer system capable of generating heat including—a box, —a water circuit capable of being connected at the inlet and at the outlet to an external water network, the water circuit includes metal pipes inside the box, —at least one panel that is kept vertically upright inside the box, the panel including a vertically upright metal pipe loop and at least one electronic board pressed vertically onto a portion of the loop, the electronic board being provided with at least one electronic component capable of generating heat towards the metal pipe, —a communication interface enabling an external computer system to access the at least one electronic component as a resource, —a control interface for regulating a quantity of energy to be generated by the at least one electronic component, —at least one power supply is disclosed.

### TECHNICAL FIELD

The present invention relates to a computer system capable of generating heat. This may be a server associated with heat removal means in a data center. Advantageously, this can be a digital boiler using microprocessors to produce heat. In this case, it is an electric boiler producing heat to heat up a water circuit.

One of the major challenges of such a digital boiler is thermal management. The aim is to maximize transmission of the heat produced to the water, while minimizing heat loss through the air contained within the boiler.

### PRIOR ART

Cooling systems for processors in data centers, for example, are well known. Such systems are individually arranged on each component to be cooled and are supplied by a specific water circuit.

Microprocessor-based boiler systems are known. A boiler equipped with multiple rows of electronic boards that can be tilted up and down for maintenance and other purposes is known.

Document FR3099814 describes a system for recovering the heat produced by an electronic or computing assembly. This system comprises a heat recovery system using a heat transfer fluid and an air heat recovery system. The heat recovered is transmitted to a thermal module.

The aim of the present invention is to develop a new heat-generating computer system that improves thermal management through temperature homogenization.

The present invention also relates to a new computer system capable of generating heat, for which maintenance is simplified.

Another aim of the invention is a new boiler that offers improved efficiency compared with current boilers.

### Disclosure of the Invention

At least one of the aforementioned objectives is achieved with a computer system capable of generating heat comprising:
a box,
a heat-transfer fluid circuit capable of being connected at the inlet and outlet to an external heat-transfer fluid network, this heat-transfer fluid circuit comprising metal pipes inside the box,
at least one panel kept vertically upright inside the box, this panel comprising a vertically upright metal pipe loop and at least one electronic board pressed vertically onto a portion of the loop, this electronic board being provided with at least one electronic component capable of generating heat towards the metal pipe,
a communication interface enabling an external computer system to access said at least one electronic component as a resource,
a control interface for regulating a quantity of energy to be generated by said at least one electronic component, and
at least one power supply.

According to the invention, the panel is attached to the box by means of a mobile fastener adapted to keep the panel vertically during a rotational or translational movement, this movement taking all or part of the panel out of the box.

The panel is attached directly or indirectly to the box.

“Vertical” and “horizontal” orientations refer to the box in its normal operating position.

The electronic component is a computing or storage resource. Ideally, it is an electronic component that generates heat when in use

The invention is particularly noteworthy in that it lies at the intersection of the field of information technology in the use of computing resources and the thermal field in the use of the system as a boiler. With the boiler according to the invention, the electronic component is used as a heat source and as a computing or storage resource for remote machines. The control interface can be user-driven or automated. Depending on a power target, this control interface regulates the activity of the electronic components so as to obtain a quantity of dissipated energy that satisfies this target.

For example, if heat is required, the control interface can order electronic components to perform calculations, each calculation or algorithm being quantified in terms of energy dissipated.

“Heat transfer fluid” means a fluid capable of conveying heat, which may be water, a gas, or any other fluid. In the following, “water” and “heat transfer fluid” will be used interchangeably. If the inlet water temperature is too high, fewer electronic components are used, or fewer calculations are performed. When the electronic component(s) is (are) used by an external computer system, the control interface takes this use into account to remain compliant with the target.

The control interface can be configured to transmit to the external computer system a signal representing the computing resource available in the boiler as a function of a setpoint. In this way, the radiator's electronic components perform calculations (controlled by the external computer system) that are sufficient in number and/or complexity to provide the amount of heat transfer energy required by the user.

The heat-generating computer system according to the invention features a novel panel or block architecture. Each panel can be seen as a page that is positioned vertically and can be pivoted relative to the box. This makes it possible to have multiple moving pages that can be pivoted in either direction.

This vertical panel architecture optimizes thermal draft. Warm air is guided upwards.

In the configuration where the panel has been pivoted or slid, the panel components are easily accessible. This makes the electronic board accessible. Maintenance can then be carried out easily.

According to the invention, the movable fastener can be a hinge enabling the panel to pivot about a vertical axis relative to the rest of the box.

According to the invention, the mobile fastener can be a rail or a sliding assembly allowing the panel to slide horizontally or vertically. In fact, the panel can be moved while remaining vertical, either by pivoting as seen above, or by translation along a rail. The sliding assembly may comprise a lifting mechanism with a counterweight. A horizontal movement allows the panel to exit the box on a side. A vertical movement allows the panel to exit from the top of the box. Ideally, the box is designed to allow movement by vertical or horizontal pivoting. However, it is also possible to envisage multiple types of movement for the same panel, or different types of movement for different panels in the same box. For example, outer panels can pivot, while inner panels can slide. A removable door or wall can be provided to allow the panel to be fully or partially removed from the box.

According to an advantageous feature of the invention, the metal pipe loop can be arranged in a serpentine configuration, with vertical sections each consisting of two parallel pipe sections capable of conveying the heat transfer fluid in two opposite directions respectively.

In other words, the pipe is arranged in a serpentine configuration in a outward direction and then in a return direction. The outward and return paths are side by side, in parallel. More precisely, on entering the panel, the metal pipe is raised vertically inside the panel, bends to straighten out vertically downwards and then bends back up again. It continues in this fashion, until a final bend is made, so that the pipe runs back in the other direction along the outward path. Each vertical section is formed by two straight, vertical pieces of pipe: one carrying water in the outward direction, the other in the return direction.

Water is then circulated within a panel to homogenize the overall temperature of each panel or page. Each vertical section comprises a pipe section in the forward direction, which is considered to convey water at a cold temperature, and a pipe section in the return direction, which is considered to convey water at a warm temperature.

Each panel or page preferably incorporates a power supply that also generates heat to be transmitted to the water circuit.

The vertical layout of the electronic boards means that many different types of electronic boards can be used, such as rack or blade boards. Other types of electronic boards can also be used.

According to one embodiment of the invention, the computer system capable of generating heat may comprise a metal block designed to capture and transfer heat, this metal block being arranged between the electronic board and the metal pipe. This metal block can be made of aluminum, copper or any other material capable of transferring heat efficiently.

The metal block maximizes the transfer of heat from the electronic component to the water circuit. Typically, the part is adapted on one side to the relief of the electronic board used, and on the other side to the metal pipes.

The metal block may comprise a receptacle to receive the electronic component protruding from the electronic board. The electronic component can also be mounted in a cavity.

Advantageously, the metal block can be made up of at least two parts, a fixed block and a modular block adapted to a given electronic board. In other words, multiple modular blocks are provided, each of which can be attached to the fixed block. Each modular block comprises recesses and/or protrusions adapted to the electronic components of a given electronic board.

According to the invention, the metal pipes intended to capture the heat coming from the metal block and containing the heat transfer fluid to be heated, are arranged between two metal blocks. These metal pipes can be made of copper or any other metallic material capable of transferring heat efficiently.

The electronic board may comprise multiple heat-generating electronic components. These heat-generating electronic components can be placed mainly on the upper part; the lower part is reserved for electronic components or heat-sensitive elements such as cables, switches, power supplies, storage disks, etc. Naturally, it's at the bottom that the temperature is lowest.

The box and vertical panel arrangement create a thermal draft that forces natural convection upwards.

According to the invention, the metal block may comprise rectilinear grooves suitable for collecting the metal pipes of the vertical section.

Ideally, pipes of the same vertical section are fixed between two metal blocks, each of which can accommodate an electronic board. The metal blocks can completely cover the surface of metal pipes.

Thus, according to the invention, the computer system capable of generating heat ideally comprises an electronic board on each side of the same vertical section.

Preferably, each panel may comprise multiple vertical sections, each vertical section being framed by two electronic boards; one vertical section can be reserved to accommodate at least one power supply. This power supply is dedicated to powering the panel components.

According to one advantageous feature of the invention, the metal pipes have an internal diameter greater than or equal to 16 mm, ideally 20 mm. This is a diameter that connects the heat-generating computer system to the water distribution network, that is, the public utility network, for example.

Such an arrangement in accordance with the present invention, with a diameter greater than 16 mm, makes it possible to use conventional tap water directly, without sanitization or with simple, low-cost filtering, and without significant head loss, thus avoiding oversizing the circulation pump. Some systems can even do without a pump specifically for boilers. The heat-generating computer system described here limits any pressure loss problems, as pipes of sufficient diameter are used.

On the contrary, in known systems for cooling electronic boards in data centers, for example, the pipes generally have a small diameter of less than 10 mm, and treated water and a heavily sized pump are used to overcome the resistance caused by the small diameter of the pipes.

According to one embodiment of the invention, when the panel can be pivoted, the cabinet may comprise a fixed leg around which the panel can be pivoted by two hinges.

The cabinet can be fitted with removable doors or walls to allow the panel to be moved outside the cabinet enclosure.

The box can be fixed to the floor or is heavy enough not to tilt when one or more panels are deployed.

Advantageously, when the panel can be pivoted, the free part of the panel, that is, the part not secured by the hinges, may comprise a retractable foot enabling it to be deployed and placed on the ground when the panel has pivoted out of the box enclosure.

This retractable foot can be used to stabilize the box when the panel is extended.

It can also be used to wedge the panel when stored in the box.

According to an advantageous embodiment of the invention, the computer system capable of generating heat may comprise a radiator arranged on the upper part of the box, perpendicular to the vertically arranged panel; the heat transfer fluid circuit being in contact with this radiator.

This radiator removes internal heat from the air.

The radiator can be a finned aluminum heatsink. It can be attached to the inlet pipe through which the water to be heated circulates. Thanks to natural convection, the hot air rises and comes into contact with the radiator at the temperature of the incoming water. This allows heat to be transferred passively from the box to the water inlet pipe.

According to the invention, at least one fan can be arranged on the radiator to force air circulation inside the box in the vertical direction. The fan circulates the air inside the cabinet, helping to homogenize the temperature. This fan can also be provided on the computing server to force thermal draft; the computing server comprising said electronic board.

According to one embodiment, the heat-generating computer system may comprise flexible hoses for connecting a metal hose portion rigidly attached to the box and the metal hose disposed in the panel.

Such an arrangement allows the panel to be pivoted while ensuring a reliable connection between different parts of the water circuit.

In addition, the heat-generating computer system may comprise multiple panels, with flexible pipes connecting the metal pipes in series between the panels.

Advantageously, the heat-generating computer system may comprise plastic structural beams to thermally insulate the box panel.

This avoids thermal bridges and retains the maximum amount of heat within the box.

Air-tightness is also ensured by the use of insulating foam, particularly at cable entry points and door edges. Ideally, the box is insulated against air and water.

According to one embodiment of the invention, the electronic component capable of generating heat can be a CPU-type microprocessor. It can also be a microcontroller, FPGA, GPU, ASIC or any other component that can be used as a computing resource and is capable of generating heat.

The electronic component can also be a data storage drive, such as an SSD (solid-state drive). An electronic board can be designed with multiple SSD drives, or a majority of them.

### DESCRIPTION OF THE FIGURES AND EMBODIMENTS.

Other benefits and features shall become evident upon examining the detailed description of entirely non-limiting embodiments and implementations, and from the following enclosed drawings:

FIG. 1 is a schematic diagram of a general external view of the boiler according to the invention,

FIG. 2 is a schematic view of the boiler according to the invention with one side wall detached,

FIG. 3 is a schematic cross-sectional view of the top of the boiler according to the invention,

FIG. 4 is a schematic perspective view of a side-open boiler panel according to the invention,

FIG. 5 is a schematic cross-sectional view of the top of the boiler according to the invention with a side-open panel according to the invention,

FIG. 6 is a schematic view of a metal pipe loop arranged in a serpentine configuration according to the invention,

FIG. 7 is a schematic top view of a metal block around the metal pipe according to the invention,

FIG. 8 is a schematic perspective view of the metal block according to the invention,

FIG. 9 is a schematic view of the electronic board and its cradle according to the invention,

FIG. 10 is a schematic top view of a metal block around the metal pipe in the presence of an electronic board attached to the metal block according to the invention,

FIG. 11 is a schematic side view of a boiler comprising a horizontally sliding panel according to the invention, and

FIG. 12 is a schematic side view of a boiler comprising a vertically sliding panel according to the invention.

The embodiments which will be disclosed hereinafter are in no way limiting; in particular, it is possible to implement variants of the invention that comprise only a selection of the features disclosed hereinafter in isolation from the other features disclosed, if this selection of features is sufficient to confer a technical benefit or to differentiate the invention with respect to the prior art. This selection comprises at least one preferably functional feature which lacks structural details, or only has a portion of the structural details if that portion only is sufficient to confer a technical benefit or to differentiate the invention with respect to the prior state of the art.

We will now describe the invention in the form of a digital boiler, although the invention is not limited thereto. Note that the invention can also be applied to heat removal systems in data centers.

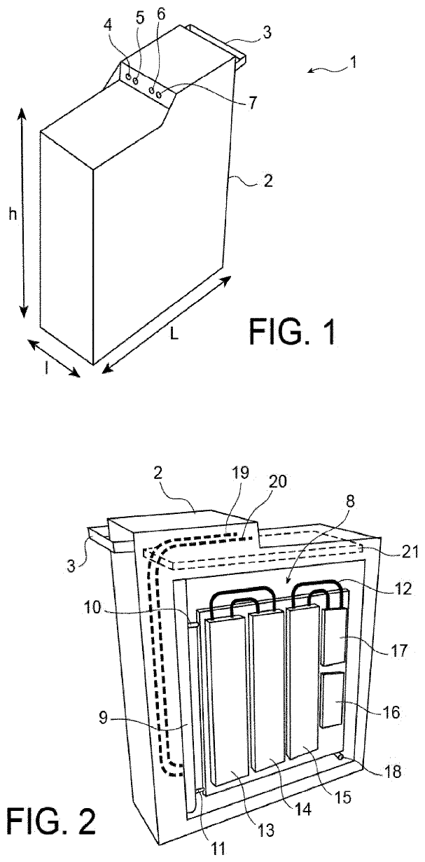

FIG. 1 is an exterior view of the boiler 1 according to the invention. There is a metal box 2, roughly parallelepipedic in shape. As a non-limiting example, the dimensions of the boiler can be 114 cm length L, 35 cm width 1 and 114 cm height h.

A handle 3 is provided across the width of the boiler, at the top, for handling.

The upper part of the boiler features a recess to accommodate inlet and outlet interfaces. There is a distinction between:
a water inlet 4, which can be directly connected to the water distribution network, e.g. the drinking water network,
an outlet 5 for hot water after passing through the box, that outlet being intended to supply a hot water network,
an input 6 for the general power supply to supply the electrical components within the boiler, this general power supply input 6 can be directly connected to the mains, that is, the conventional electrical network,
one or more fiber-optic network connectors for data communication between the boiler and the outside world.

In the installed position, the boiler 1 is designed to be taller than it is wide.

FIG. 2 is a schematic perspective view of the boiler 1 with one side wall removed. This may be a removable wall or a door that can be opened by pivoting on hinges (not shown) attached to one of the four edges defining the opening in FIG. 2.

A panel 8 can be distinguished in the form of a vertical page positioned in a plane comprising the length and height of the box.

A fixed foot 9 made of metal or hard plastic stands vertically in the direction of the box height.

The foot 9 acts as a mast to support the panel 8 by means of two hinges 10 and 11. As a result, the panel 8 can be pivoted about an axis passing through the fixed foot 9 and thus exit the box 2.

The panel 8 comprises a metal pipe 12 in serpentine configuration running through the panel in several vertical sections. Three electronic board cradles 13, 14 and 15 can be distinguished, generally corresponding to three vertical sections. A final vertical section comprises two power supplies 16 and 17. A retractable foot 18 is provided to hold the fixed panel inside the box and to be deployed by touching the ground when the panel 8 is open.

FIG. 2 shows, very schematically as dotted lines, two pipes 19 and 20, one between the water inlet to the boiler and the bottom of the foot 9, the other between the water outlet from the boiler and the bottom of the foot 9. Hoses are provided to connect pipes 19 and 20 to the inlet and outlet of the loop formed by the pipe 12. These two pipes 19 and 20, which form part of the water circuit, pass through a radiator 21 located at the top of the boiler. In this way, the heat coming from the electronic boards and rising by thermal draft comes into contact with the radiator to heat pipes 19 and 20. This creates a natural form of preheating. Fans can be provided under the radiator, for example in contact with the lower surface of the radiator, to promote air circulation.

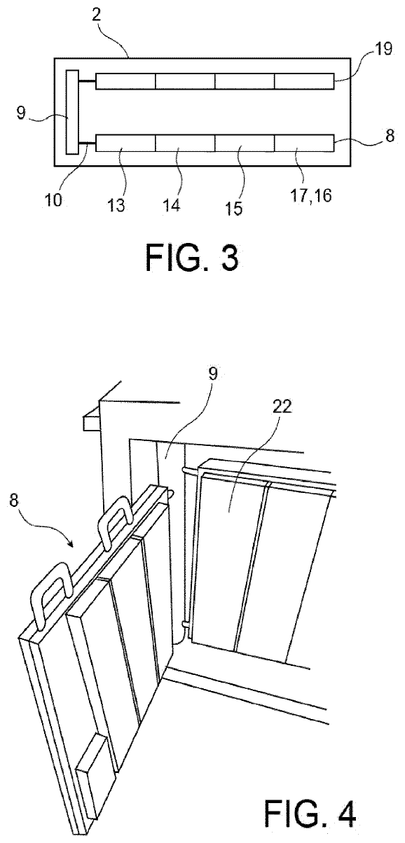

FIG. 3 is a schematic cross-sectional view of the top of the boiler. Inside the box 2, the foot 9 is integral with the box and remains fixed. The panel 8 is shown with four sections 13, 14, 15 and the assembly 16 and 17. A further panel 22 is also visible, constructed in the same way as the panel 8 and can be extended outwards on the side opposite the panel 8. However, the same foot 9 or a narrow foot, equipped with the same hinges or other types of hinges, particularly sliding hinges, can also be envisaged, enabling the panel 22 to be deployed on the same side as the panel 8. In this way, both panels can be accessed from the same side during maintenance operations.

More than two panels can also be arranged inside the same box.

The panel arrangement shown in FIG. 3 creates empty vertical columns wherein air circulates within the box. This arrangement encourages circulation from bottom to top. The vertical arrangement of the pipes, with a parallel round trip, also ensures better temperature distribution inside the box.

The vertical orientation of the panels facilitates the placement of electronic boards, and allows certain temperature-sensitive components to be placed at the bottom.

FIG. 4 is a perspective view of the open panel 8. The foot 9 and panel 22 are still visible.

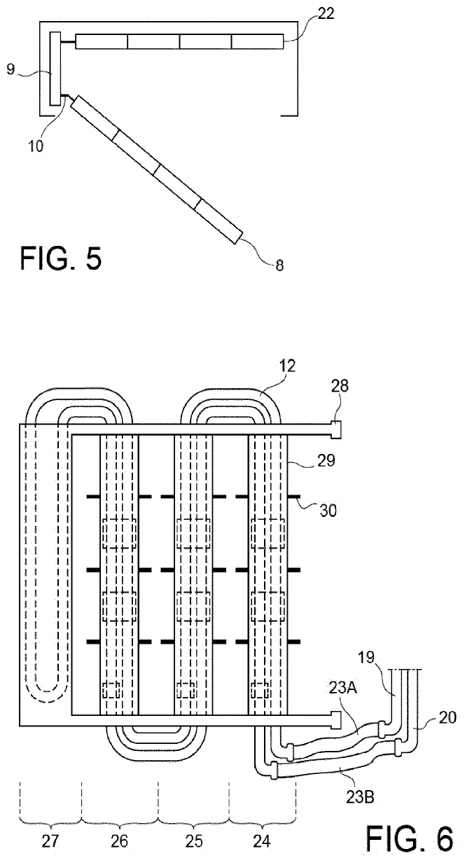

FIG. 5 is a schematic cross-sectional view of the top of the boiler as shown in FIG. 4. Inside the box 2, the fixed foot 9 is visible.

The panel 8 is deployed towards the outside of the box. Depending on the hinges used, the panel can be fully or partially extended outside the box 2.

We can now describe the construction of a panel.

FIG. 6 is a schematic view of the metal pipe 12 arranged in a serpentine configuration in the panel. This pipe 12 is fed by the inlet pipe 19 via a hose 23A. The return pipe 12 supplies the outlet pipe 20 or a second panel 22 via the hose 23B.

The forward path of the pipe 12 starts from the hose 23A, rises vertically in vertical section 24, turns and then returns downwards in the vertical section 25. The route then continues via the vertical section 26 to the vertical section 27.

The pipe 12 then undergoes a bend and returns in the opposite direction, parallel to the first run. Thus, in each section, the pipe 12 runs twice: in one direction and then in the other.

With the boiler according to the invention, water circulation between the vertical sections takes place in such a way as to homogenize the overall temperature on a panel.

In the example shown in FIG. 6, the vertical section 27 is designed to accommodate two power supplies 16 and 17. The distance between the outward pipe and the return pipe in the vertical section 27 is slightly greater than in other vertical sections.

The invention uses copper pipes of conventional plumbing dimensions, so that the boiler can be directly connected to the water distribution network.

FIG. 6 also shows a frame 28 to hold the assembly rigidly in place. Each vertical section 24-26 is equipped with two metal blocks 29 framing the two pipes 12.

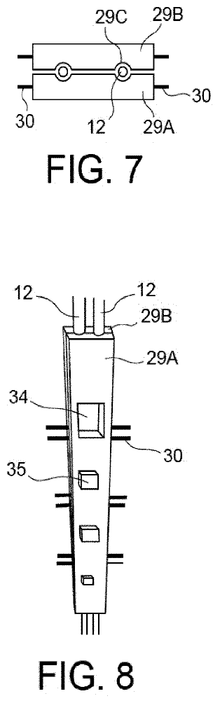

FIG. 7 is a cross-sectional view showing two metal blocks 29A and 29B enclosing the two pipes 12. Ideally, the two metal blocks come into contact. Internal grooves 29C are provided to house the two pipes 12 completely inside the assembly 29A and 29B.

FIG. 8 is a schematic perspective view of metal blocks 29A and 29B. A distinction is made between supports 30 and receptacles 34 and 35, which may be protuberances or recesses designed to come into contact with electronic components capable of generating heat.

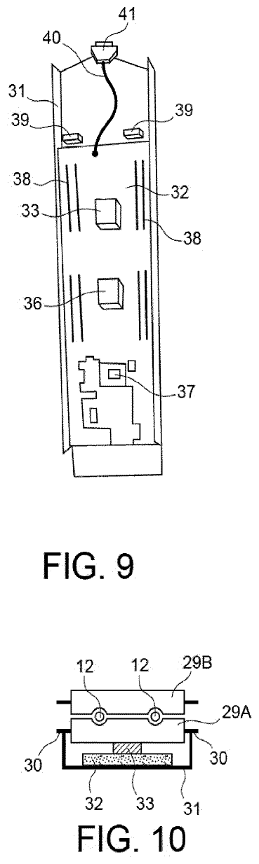

These components 33 and 36 are shown in FIG. 9. They are arranged on an electronic board 32 comprising memories 38 and other components such as chipsets 37. The electronic components capable of generating heat 33 and 36 are, for example, microprocessors. The receptacles 34 and 35 are designed to match the face of electronic components 33 and 36. Contact between the electronic component and its receptacle is facilitated by the use of a thermal paste.

On the chipsets, a thicker thermal pad is used than thermal paste. In this way, priority is given to the precision of the contact between the receptacle and the microprocessors, and an approximation of the chipset contact is tolerated.

Generally speaking, thermal paste is used to plate the electronic component that heats up the most effectively on the metal block.

Then, for other electronic components that heat up less, the metal block is designed to also recover a maximum amount of heat, but without compromising the arrangement intended for the electronic component that heats up the most. In this way, a larger pad can be used to connect low-heating electronic components to the metal block with a certain tolerance.

Then, the heat generated by the rest of the components is evacuated by the air circulating in the box.

The electronic board 32 is contained in a cradle 31.

Power and communication cables 40 are provided between the electronic board 32 and one or more connectors 41 fixed to the cradle 31.

Fans 39 are provided on the cradle to help move the air upwards.

The cradle 31, carrying the electronic board 32, is designed to engage with the metal block 29A and to be held in place by the supports 30. Notches (not shown) on the cradle 31 are specially designed to engage with the supports 30.

FIG. 10 is a cross-sectional view showing the cradle 31 pressed against the metal block 29A.

The electronic component 33 is in contact with the metal block 29A. The supports 30 hold the cradle 31 stationary.

When the electronic component 33 heats up, the heat is efficiently transmitted to the water-carrying pipes 12.

The cradle 31 in FIGS. 9 and 10 corresponds, for example, to the front of section 15 in FIG. 2.

Heat pipes can be integrated into the metal block to better diffuse heat into and through the metal block and recover it from the water circuit.

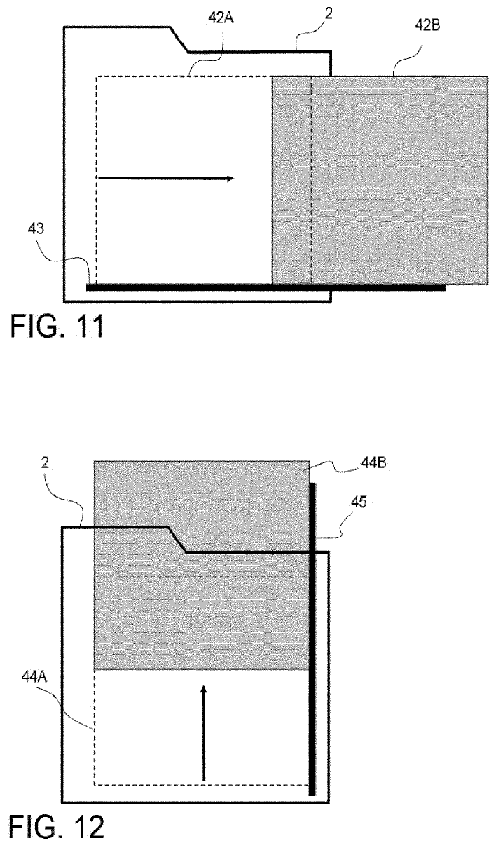

FIG. 11 shows a boiler according to the invention in a horizontally sliding panel embodiment. The box 2 encloses the panel 42 in its operating position 42A shown as dotted lines. This panel 42 is placed on a sliding rail 43 and can be held solely by the rail 43 or by other holding means not shown, such as a fixed foot. Alternatively, a second rail can be positioned along the panel on another side of the panel, parallel to the first rail. In the operating position, the rail 43 is completely inside the box 2. In the maintenance position, for example, the panel 42 moves to position 42B partially outside the box 2. The rail 43 is of the sliding type, enabling the panel 42 to be moved outside the box 2. A non-sliding rail remaining inside the box is also an option.

FIG. 12 shows a boiler according to the invention in a vertically sliding panel embodiment. The box 2 encloses the panel 44 in its operating position 44A shown as dotted lines. This panel 44 is held by a sliding rail 45 and can be held solely by the rail 45 and/or by other holding means not shown. A second rail can be positioned along the panel on another side of the panel, parallel to the first rail. In the operating position, the rail 45 is completely inside the box 2. In the maintenance position, for example, the panel 44 moves to position 44B partially outside the box 2. The rail 45 is of the sliding type, enabling the panel 44 to be moved outside the box 2. A non-sliding rail remaining inside the box is also an option.

The present invention thus enables good thermal management inside the boiler. By various means, it helps to transfer heat to the water, preventing the atmosphere inside the boiler from heating up too easily and transmitting this heat outside the boiler.

Of course, the invention is not limited to the examples disclosed above. Many modifications can be made to these examples without departing from the scope of the present invention as disclosed.

1. A computer system capable of generating heat, comprising:
a box;
a heat-transfer fluid circuit capable of being connected at the inlet and outlet to an external heat-transfer fluid network, said heat-transfer fluid circuit comprising metal pipes inside the box;
at least one panel kept vertically upright inside the box, said panel comprising a vertically upright metal pipe loop and at least one electronic board pressed vertically onto a portion of the loop, said electronic board being provided with at least one electronic component capable of generating heat towards the metal pipe;
a communication interface enabling an external computer system to access said at least one electronic component as a resource;
a control interface for regulating a quantity of energy to be generated by said at least one electronic component; and
at least one power supply;
the panel is attached to the box by means of a mobile fastener constructed and arranged for keeping the panel vertically during a rotational or translational movement, said movement taking all or part of the panel out of the box.

2. The system according to claim 1, characterized in that the movable fastener is a hinge enabling the panel to pivot about a vertical axis relative to the rest of the box.

3. The system according to claim 1, characterized in that the movable fastener is a rail allowing the panel to slide horizontally or vertically.

4. The system according to claim 1, characterized in that the metal pipe loop is arranged in a serpentine configuration with vertical sections each consisting of two parallel pipe parts suitable for conveying the heat transfer fluid in two opposite directions respectively.

5. The system according to claim 1, further including a metal block designed to capture and transfer heat, said metal block being arranged between the electronic board and the metal pipe.

6. The system according to claim 5, characterized in that the metal block comprises rectilinear grooves suitable for collecting the metal pipes of the vertical section.

7. The system according to claim 5, characterized in that the metal block consists of at least two parts, a fixed block and a modular block adapted to a given electronic board.

8. The system according to claim 1, further including an electronic board on each side of the same vertical section.

9. The system according to claims claim 1, characterized in that each panel comprises multiple vertical sections, each vertical section being framed by two electronic boards; one vertical section being reserved for arranging at least one power supply.

10. The system according to claim 1, characterized in that the metal pipes have an internal diameter greater than or equal to 16 mm.

11. The system according to claim 1, characterized in that when the panel is pivotable, the cabinet comprises a fixed foot about which the panel can be pivoted via two hinges.

12. The system according to claim 1, characterized in that the box is provided with removable doors or walls enabling the panel to be moved out of the box enclosure.

13. The system according to claim 1, characterized in that when the panel is pivotable, the free part of the panel comprises a retractable foot enabling it to be deployed and placed on the ground when the panel has pivoted out of the box enclosure.

14. The system according to claim 1, further including a radiator disposed on the upper part of the box, perpendicular to the vertically disposed panel; the heat transfer fluid circuit being in contact with this radiator.

15. The system according to claim 14, characterized in that at least one fan is arranged on the radiator to force air circulation inside the box in the vertical direction.

16. The system according to claim 1, further including flexible hoses for connecting a metal hose portion rigidly attached to the box and the metal hose disposed in the panel.

17. The system according to claim 1, further including multiple panels, with flexible pipes connecting the metal pipes in series between the panels.

18. The system according to claim 1, further including plastic structural beams for thermally insulating the box panel.

19. The system according to claim 1, characterized in that the electronic component capable of generating heat is a microprocessor.

20. The system according to claim 1, characterized in that the electronic component is a data storage disk.
